(19) United States
(12) Patent Application Publication
(10) Pub. No.: US 2025/0015076 A1
(43) Pub. Date: Jan. 9, 2025

(54) SEMICONDUCTOR DIE WITH GROUP III NITRIDE-BASED AMPLIFIER CIRCUITS

(71) Applicant: MACOM Technology Solutions Holdings, Inc., Lowell, MA (US)

(72) Inventors: Simon Maurice Wood, Morgan Hill, CA (US); Michael E. Watts, Scottsdale, AZ (US); Sonoko Akamatsu Aristud, Chandler, AZ (US); Zoran Anusic, Phoenix, AZ (US)

(21) Appl. No.: 18/764,815

(22) Filed: Jul. 5, 2024

Related U.S. Application Data
(60) Provisional application No. 63/512,417, filed on Jul. 7, 2023.

(51) Int. Cl. H01L 27/06

(52) U.S. Cl. CPC H01L 27/0605; H01L 28/10

(57) ABSTRACT

A number of semiconductor die with Group III nitride-based amplifier circuits are described. In one example, the semiconductor die includes a first Group III nitride-based transistor having a first output contact. The semiconductor die includes a second Group III nitride-based transistor having a second output contact. The semiconductor die includes an output combiner inductor on the semiconductor die. The output combiner inductor may be coupled to the first output contact and to the second output contact. The output combiner inductor may further be coupled to a radio frequency (RF) output interface for the semiconductor die.

### CROSS-REFERENCE TO RELATED APPLICATIONS

This application claims the benefit of and priority to U.S. Provisional Patent Application Ser. No. 63/512,417, titled “COMPACT SEMICONDUCTOR DIE WITH GROUP III NITRIDE-BASED AMPLIFIER,” filed Jul. 7, 2023, the entire contents of which is hereby incorporated herein by reference.

### BACKGROUND

High frequency driver amplifiers are used in a wide range of communications, radar, and related radio frequency (RF) systems. It may be desirable in some applications for such driver amplifiers to have wide bandwidth and operate with high efficiency, among other operating characteristics of interest. Doherty amplifiers, as an example amplifier circuit topology, may be well-suited for such applications. A Doherty amplifier may provide increased efficiency while maintaining signal linearity. A Doherty amplifier may use a combination of two or more amplifiers (e.g., a carrier or base amplifier and one or more peaking amplifiers) to achieve higher efficiency at both low and high-power levels. Power semiconductor devices for driver amplifiers in Doherty and related amplifiers may be fabricated from wide bandgap semiconductor materials. High electron mobility transistors (HEMTs), for example, may be fabricated from gallium nitride (GaN) or other Group III nitride-based materials formed, for instance, on a silicon, silicon carbide, or other substrate.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example semiconductor die includes a first Group III nitride-based transistor over a substrate and having a first output contact, a second Group III nitride-based transistor over the substrate and having a second output contact, an output combiner inductor over the substrate, the output combiner inductor being coupled to the first output contact and to the second output contact, and a radio frequency (RF) output interface coupled to the output combiner inductor.

Another example semiconductor die includes a first Group III nitride-based transistor over a substrate, a second Group III nitride-based transistor over the substrate, a first input matching circuit over the substrate and coupled to a gate of the first Group III nitride-based transistor, and a second input matching circuit over the substrate and coupled to a gate of the second Group III nitride-based transistor.

An example monolithic microwave integrated circuit (MMIC) includes a first Group III nitride-based transistor over a substrate, a second Group III nitride-based transistor over the substrate, a first input matching circuit over the substrate and coupled to a gate of the first Group III nitride-based transistor, a second input matching circuit over the substrate and coupled to a gate of the second Group III nitride-based transistor, an output combiner inductor over the substrate, and a radio frequency (RF) output interface coupled to the output combiner inductor. The output combiner inductor can be coupled to a first output contact of the first Group III nitride-based transistor and to a second output contact of the second Group III nitride-based transistor.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 depicts a schematic block diagram of an example Doherty amplifier.

FIG. 2 depicts a layout of an example semiconductor die associated with an amplifier circuit according to example embodiments of the present disclosure.

FIG. 3 depicts a circuit diagram of the amplifier circuit associated with the semiconductor die shown in FIG. 2 according to example embodiments of the present disclosure.

FIG. 4 depicts a layout of an example semiconductor die associated with an amplifier circuit according to example embodiments of the present disclosure.

FIG. 5 depicts a circuit diagram of the amplifier circuit associated with the semiconductor die shown in FIG. 4 according to example embodiments of the present disclosure.

FIG. 6 depicts a layout of an example semiconductor die associated with an amplifier circuit according to example embodiments of the present disclosure.

FIG. 7 depicts a circuit diagram of the amplifier circuit associated with the semiconductor die shown in FIG. 6 according to example embodiments of the present disclosure.

FIG. 8 depicts a layout of an example semiconductor die associated with an amplifier circuit according to example embodiments of the present disclosure.

FIG. 9 depicts a circuit diagram of the amplifier circuit associated with the semiconductor die shown in FIG. 8 according to example embodiments of the present disclosure.

FIG. 10 depicts a cross sectional view of an example unit cell of a high electron mobility transistor (HEMT) device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. It will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of semiconductor die with Group III nitride-based amplifier circuits are described. The semiconductor die can be relied upon as compact radio frequency (RF) amplifiers, including as monolithic microwave integrated circuit (MMIC) amplifiers in some cases. The semiconductor die concepts described herein are applicable to a range of different RF amplifiers, such as Doherty and other types of RF amplifiers. A typical Doherty amplifier includes a combination of a main or carrier amplifier and one or more peaking amplifiers coupled in parallel, and a range of Doherty-type amplifier circuit topologies are known. The carrier amplifier handles the bulk of the input RF signal power in some implementations, and the peaking amplifier selectively amplifies the RF signal during high-power transmission periods. This configuration allows the Doherty amplifier to achieve signal linearity over a wide range of RF signal power, making the Doherty amplifier a suitable choice in various wireless communication systems, such as multiple-input and multiple-output (MIMO) based communication systems.

Semiconductor devices, such as high electron mobility transistors (HEMTs), may be used in RF amplifier applications. HEMTs fabricated using Group III nitride-based material systems have the potential to generate large amounts of RF power because of the combination of material characteristics including high breakdown fields, wide bandgaps, large conduction band offsets, high saturated electron drift velocities, and related characteristics. As such, Group III nitride-based HEMTs are good candidates for high frequency high-power RF applications, as well as for low frequency high-power switching applications.

Aspects of the present disclosure are directed to implementing an amplifier circuit, such as a Doherty amplifier circuit, using one or more Group III nitride-based transistors on a compact wide bandgap semiconductor die. One or more aspects of the amplifier circuit may be implemented as lumped elements (e.g., inductors, capacitors, transmission lines, etc.) within the white space on a semiconductor die or substrate to provide high performance with a relatively small increase in semiconductor die size at reduced costs as compared to other approaches.

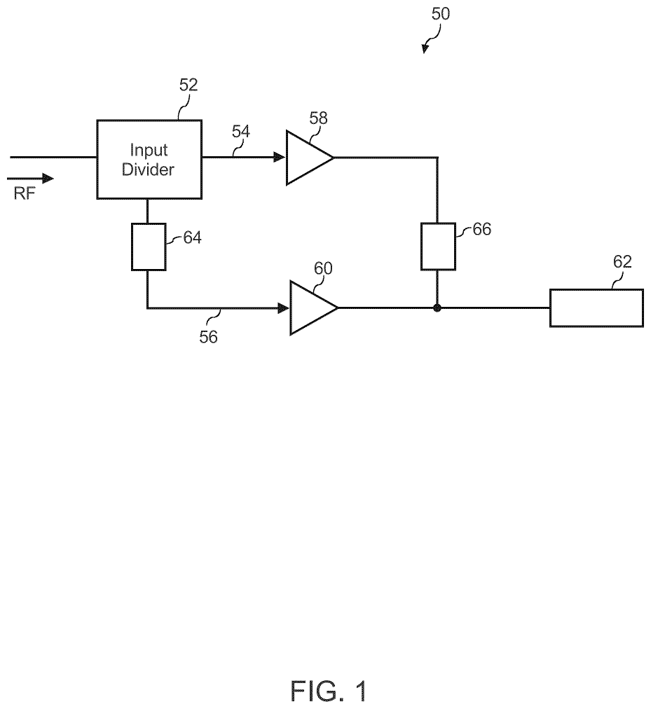

FIG. 1 depicts a schematic block diagram of an example Doherty amplifier 50. The Doherty amplifier 50 is provided as a representative example and for context to describe the embodiments. The concepts described herein are applicable to other types and topologies of amplifiers, including both Doherty and other amplifiers. The schematic block diagram of the Doherty amplifier 50 is not exhaustively illustrated, and the Doherty amplifier 50 can include other components that are not shown. The Doherty amplifier 50 can also omit one or more of the components shown in FIG. 1 in some cases.

The Doherty amplifier 50 includes an RF input power divider 52. The RF input power divider 52 can split an RF signal into a first path 54 and a second path 56. The first path 54 may include a carrier amplifier 58. The second path 56 may include a peaking amplifier 60. The carrier amplifier 58 may be operable to handle the bulk of the input RF signal power, while the peaking amplifier 60 selectively amplifies the RF signal during high-power transmission periods. The output of the carrier amplifier 58 and the peaking amplifier 60 may be combined and used to drive a load 62. The load 62 can be embodied or implemented as an antenna or other interface of a communication system, such as a MIMO-based communication system. In some examples, a phase shifter 64 (e.g., a 90° phase shifter or λ/4 phase shifter) may be implemented in the second path 56 prior to the peaking amplifier 60. A phase shifter 66 (e.g., a 90° phase shifter or λ/4 phase shift) may also be implemented in the first path 54 after the carrier amplifier 58 as shown in FIG. 1.

The RF input power divider 52 can be embodied as a lumped Wilkinson power divider circuit in one example, although the RF input power divider 52 can also be implemented as other types of divider circuits and circuit configurations. In some embodiments, the RF input power divider 52 may provide a substantially even power division between the carrier amplifier and the peaking amplifier. In other cases, however, the RF input power divider 52 may provide a different power division. For example, the power division of the RF input power divider 52 and the biasing of the peaking amplifier 60 can be selected or varied to vary the turn-on power for the peaking amplifier and a knee of an output power/efficiency curve (“back-off” power level) of the Doherty amplifier 50.

In some examples, the RF input power divider 52 is not a Wilkinson power divider. Rather, the RF input power divider 52 may simply be a node where two or more separate paths (e.g., first path 54 and second path 56) are split from a common path. The two separate paths may have the same impedance or differing impedance depending on a desired RF power split between the carrier amplifier 58 and the peaking amplifier 60.

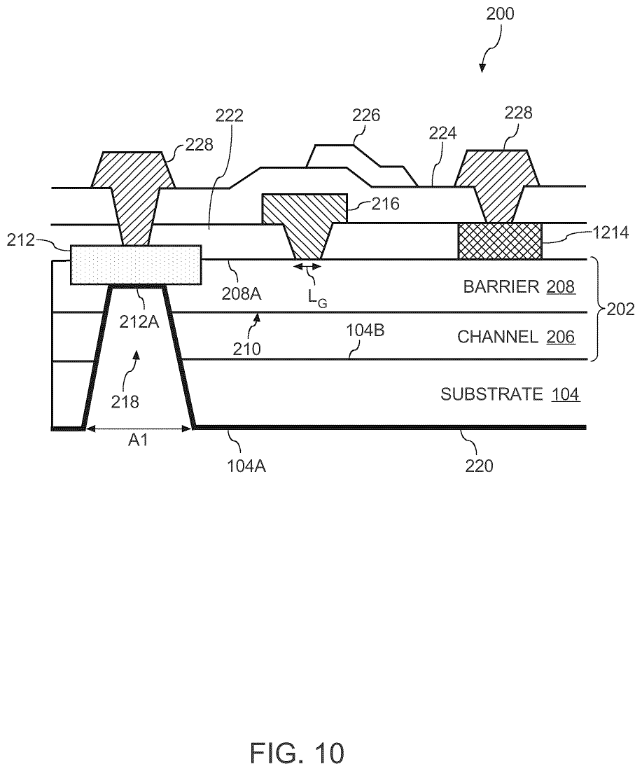

The carrier amplifier 58 and the peaking amplifier 60 can each be embodied as one or more power transistor amplifiers or amplifier circuits, including multistage power amplifier circuits. According to example aspects of the present disclosure, the carrier amplifier 58 and the peaking amplifier 60 are implemented using Group III nitride-based HEMTs. Example Group III nitride-based HEMTs are discussed in further detail below with reference to FIG. 10.

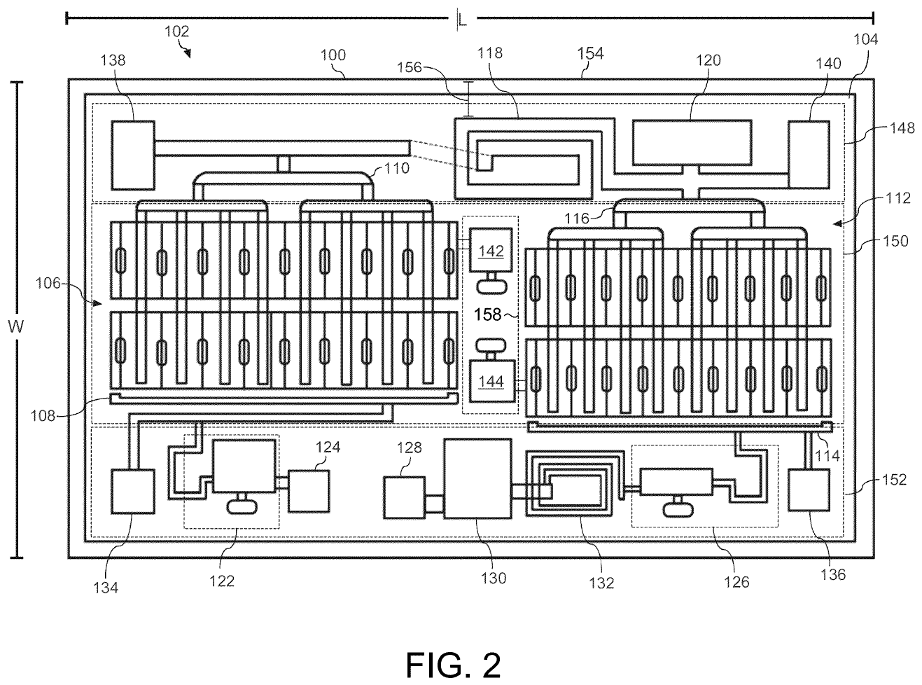

FIG. 2 depicts an example semiconductor die 100. The semiconductor die 100 is provided as a representative example. The features of the semiconductor die 100 are not exhaustively illustrated, and the semiconductor die 100 can include other components or features that are not shown. The semiconductor die 100 can also omit one or more of the components shown in FIG. 2 in some cases. The semiconductor die 100 can be used to implement aspects of an amplifier circuit 102, such as a Doherty amplifier circuit, according to example embodiments of the present disclosure. The semiconductor die 100 can be embodied as a type of MMIC including a range of active and passive circuit components implemented over a single common substrate in one example, but it is not necessary for the semiconductor die 100 to be implemented as a MMIC in all cases.

The semiconductor die 100 includes a substrate 104, such as a monolithic wide bandgap semiconductor substrate. In some examples, the substrate 104 can be embodied as a silicon carbide substrate. However, other suitable substrates may be used without deviating from the scope of the present disclosure, such as silicon, sapphire, and other suitable substrates including those described below. The substrate 104 can include one or more semiconductor material layers formed in a stack over a base substrate or wafer. The semiconductor material layers can include one or more doped and undoped layers of gallium nitride materials, for example, such as a gallium nitride material conduction layer for Group III nitride-based transistors. The semiconductor material layers can include one or more heterojunctions for active devices as would be understood in the field. These and other aspects are also described in further detail below with reference to FIG. 10.

The semiconductor die 100 includes a first Group III nitride-based transistor 106 (also “first transistor 106”) formed at least in part in, on, and over the substrate 104. The first transistor 106 may include one or more unit cell transistor devices, such as one or more unit cell HEMT devices. An example unit cell HEMT device is described in further detail below with reference to FIG. 10. The first transistor 106 may be used to implement a main, carrier, or related amplifier according to example embodiments of the present disclosure. Among other features, the first transistor 106 includes an input contact 108 and an output contact 110. The input contact 108 can be embodied as or coupled to a gate contact of the first transistor 106. The output contact 110 can be embodied as or coupled to a drain contact for the first transistor 106.

The semiconductor die 100 includes a second Group III nitride-based transistor 112 (also “second transistor 112”) formed at least in part in, on, and over the substrate 104. The second transistor 112 may include one or more unit cell transistor devices, such as one or more unit cell HEMT devices. The second transistor 112 may be used to implement a peaking amplifier or related amplifier according to example embodiments of the present disclosure. Among other features, the second transistor 112 may include an input contact 114 and an output contact 116. The input contact 114 can be embodied as or coupled to a gate contact for the second transistor 112. The output contact 116 can be embodied as or coupled to a drain contact for the second transistor 112.

The semiconductor die 100 includes lumped elements on the substrate 104 to implement aspects of the amplifier circuit 102. For instance, as shown in FIG. 2, the semiconductor die 100 includes an output combiner inductor 118. The output combiner inductor 118 may be, for instance, a lumped element that is coupled to the output contact 110 of the first transistor 106 and the output contact 116 of the second transistor 112. In some examples, the output combiner inductor 118 is a spiral inductor. The output combiner inductor 118 may combine the outputs of the first transistor 106 and the second 112. The output combiner inductor 118 may be configured to implement a phase shift (e.g., 90° phase shift or λ/4 phase shift) in the RF signal from the output contact 110 from the first transistor 106. The output combiner inductor 118 may be coupled to the RF output interface 120 of the semiconductor die 100. In some examples, the output combiner inductor 118 may provide an RF output impedance for the semiconductor die 100 at the RF output interface 120 of about 10 Ohms or greater. The output combiner inductor 118 can also provide other RF output impedances greater or less than 10 Ohms in other cases.

The semiconductor die 100 may also include a first input matching circuit 122 on the substrate 104. The first input matching circuit 122 may be coupled to the input contact 108 of the first transistor 106. The first input matching circuit 122 may be coupled to a first RF input interface 124 on the semiconductor die 100. The first RF input interface 124 can be embodied as a first input contact. The first input matching circuit 122 may include one or more lumped elements (e.g., inductors, capacitors, and other passive components) to provide an impedance match between the first RF input interface 124 and the first transistor 106.

The semiconductor die 100 may also include a second input matching circuit 126 on the substrate 104. The second input matching circuit 126 may be coupled to the input contact 114 of the second transistor 112. The second input matching circuit 126 may be coupled to a second RF input interface 128 on the semiconductor die 100. The second RF input interface 128 can be embodied as a second input contact. The second input matching circuit 126 can be coupled to the second RF input interface 128 through a DC blocking capacitor 130 and a phase shifter inductor 132 on the semiconductor die 100 in one example, although the coupling can be implemented in other ways. The second input matching circuit 126 may include one or more lumped elements (e.g., passive inductors and capacitors) to provide an impedance match between the second RF input interface 128 and the second transistor 112. The DC blocking capacitor 130 may be operable to block DC components of the RF signal from the second RF input interface 128. The phase shifter inductor 132 may be operable to implement a phase shift (e.g., 90° phase shift or λ/4 phase shift) in the RF signal from the second RF input interface 128. The RF input impedance of the semiconductor die 100 may be about 10 Ohms or greater in one example, although the RF input impedance of the semiconductor die 100 can be greater or less than 10 Ohms in other cases.

In the example semiconductor die 100 of FIG. 2, an RF input power divider for dividing an RF signal is located “off chip” (e.g., not on the semiconductor die 100). The off-chip RF input power divider (e.g., a Wilkinson input divider) may divide an RF signal into two or more paths. A first path may be coupled to the first RF input interface 124. A second path may be coupled to the second RF input interface 128.

The semiconductor die 100 may include other interfaces. For instance, the semiconductor die 100 may include a first gate interface 134 on the substrate 104 for the first transistor 106. The semiconductor die 100 may also include a second gate interface 136 on the substrate 104 for the second transistor 112.

The semiconductor die 100 may include a first drain interface 138 (e.g., first drain bias interface) on the substrate 104 for the first transistor 106. The first drain interface 138 can be embodied as a first drain bias interface for the first transistor 106, as an example interface. The semiconductor die 100 may also include a second drain interface 140 on the substrate 104 for the second transistor 112. The second drain interface 140 can be embodied as a second drain bias interface for the second transistor 112, as an example interface.

In some examples, the semiconductor die 100 may include a first source interface 142 on the substrate 104 for the first transistor 106. In some examples, the first source interface 142 is coupled to a ground or reference. The semiconductor die 100 may include a second source interface 144 on the substrate 104 for the second Group III nitride-based transistor 112. In some examples, the second source interface 144 is coupled to a ground or reference.

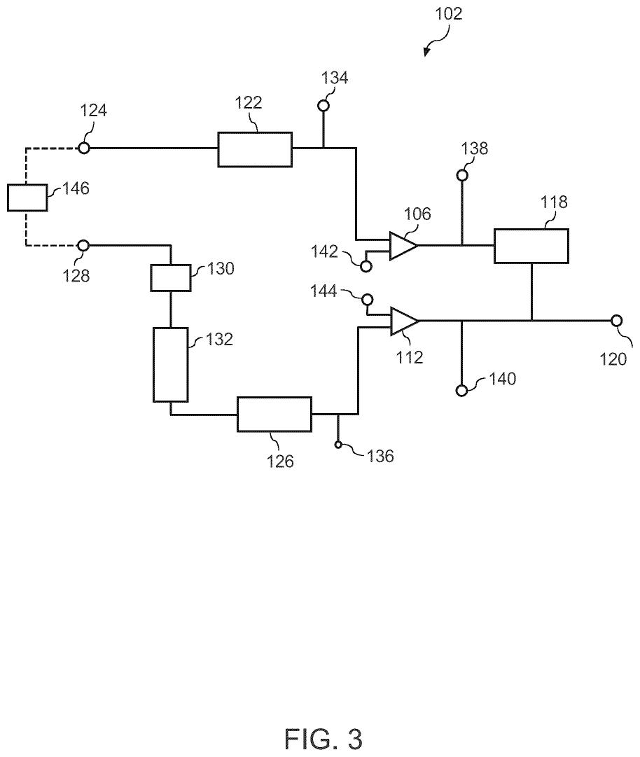

FIG. 3 is a circuit diagram corresponding to the amplifier circuit 102 on the semiconductor die 100 of FIG. 2. As shown, an “off chip” RF input power divider 146 (e.g., Wilkinson input divider) may divide an input RF signal and provide a RF signal to the first RF input interface 124 on the semiconductor die 100 and a second RF signal to the second RF input interface 128 on the semiconductor die 100. The first RF signal may pass through the first input matching circuit 122 to the first transistor 106, which acts as a main or carrier amplifier. The second RF signal may pass through the DC blocking capacitor 130, the phase shifter inductor 132, and the second input matching circuit 126 to the second transistor 112, which acts as a peaking amplifier. The output of the first transistor 106 may pass through the output combiner inductor 118 and combine with the output of the second transistor 112 to provide an RF output via the RF output interface 120 to a load. The load can be embodied as one or more antennas in a wireless communications system, as one example.

Referring back to FIG. 2, the arrangement of elements on the semiconductor die 100 facilitates the implementation of the amplifier circuit 102 in a relatively compact format. The semiconductor die 100 may include a length L. The length L may be the long dimension associated with a surface of the semiconductor die 100. The length L of the semiconductor die 100 may be about 2.8 mm or less, such as in a range of about 2.3 mm to about 2.8 mm, such as about 2.5 mm. The semiconductor die 100 may have a width W. The width W may be the short dimension associated with a surface of the semiconductor die 100. The width W of the semiconductor die 100 may be about 1.5 mm or less, such as in a range of about 1.2 mm to about 1.5 mm, such as about 1.4 mm. The semiconductor die 100 may have a surface area (e.g., the surface area of the surface including the elements of the amplifier circuit 102). The surface area may be about 4.2 mm² or less, such as in a range of about 2.7 mm² to about 4.2 mm², such as about 3.2 mm². The length L, width W, and surface area dimensions of the semiconductor die 100 can vary as compared to the example dimensions described above, however, depending on the implementation and design needs for the amplifier circuit 102. The substrate 104 can also be defined according to the example length L, width W, and surface area dimensions described above.

The layout of the circuit elements or components of the amplifier circuit 102 on the semiconductor die 100 can be tailored to facilitate the implementation. Reference is made below to rectangular regions of the semiconductor die 100 and the substrate 104. Comparing the positions of each region, the regions define example layout arrangements of the elements of the amplifier circuit 102. The regions are described as being rectangular, but the positional relationships can be understood using regions of different shapes. As examples, referring to FIG. 2, the semiconductor die may have a first rectangular region 148, a second rectangular region 150, and a third rectangular region 152. The second rectangular region 150 is between the first rectangular region 148 and the third rectangular region 152. There is no overlap between the first rectangular region 148, the second rectangular region 150, and the third rectangular region 152. The output combiner inductor 118 is in the first rectangular region 148. The first transistor 106 and the second transistor 112 are in the second rectangular region 150. The first input matching circuit 122 and the second input matching circuit 126 are in the third rectangular region 152.

In some examples, the first drain interface 138 is in the first rectangular region 148. The second drain interface 140 is in the first rectangular region 148. The RF output interface 120 is in the first rectangular region 148. The output combiner inductor 118 is in a region between the first drain interface 138 and the second drain interface 140. The RF output interface 120 is in a region between the output combiner inductor 118 and the second drain interface 140.

The output combiner inductor 118 may be proximate to a peripheral edge 154 of the semiconductor die 100. There may be no intervening elements associated with the amplifier circuit 102 in a region 156 between the output combiner inductor 118 and the peripheral edge 154 of the semiconductor die 100.

The output combiner inductor 118 is not in the second rectangular region 150. In some examples, the second rectangular region 150 may include a region 158 defined between the first transistor 106 and the second transistor 112. The output combiner inductor 118 is not in the region 158 defined between the first transistor 106 and the second transistor 112. In some examples, the first source interface 142 is in the region 158 defined between the first transistor 106 and the second transistor 112. In some examples, the second source interface 144 is in the region 158 defined between the first transistor 106 and the second transistor 112.

In some examples, the first RF input interface 124 is in the third rectangular region 152. The second RF input interface 128 is in the third rectangular region 152. The DC blocking capacitor 130 is in the third rectangular region 152. The phase shifter inductor 132 is in the third rectangular region 152. The first gate interface 134 is in the third rectangular region 152. The second gate interface 136 is in the third rectangular region 152. The first gate interface 134 may be located in a region on the semiconductor die 100 between the first input matching circuit 122 and a peripheral edge of the semiconductor die 100. The second gate interface 136 may be located between the second input matching circuit 126 and a peripheral edge of the semiconductor die 100.

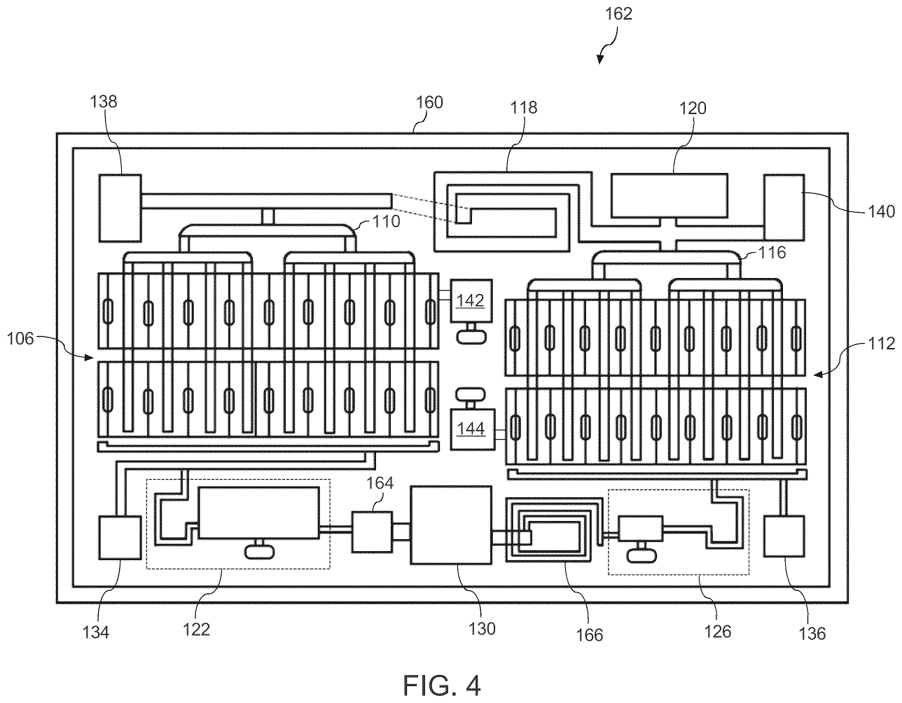

FIG. 4 depicts an example semiconductor die 160 that may be used to implement aspects of an amplifier circuit 162, such as a Doherty amplifier circuit, according to example embodiments of the present disclosure. The semiconductor die 160 may be associated with a MMIC including a range of active and passive circuit components implemented over a single common substrate in one example, but the semiconductor die 170 is not limited to implementation as a MMIC in all cases. The semiconductor die 160 is provided as a representative example. The features of the semiconductor die 160 are not exhaustively illustrated, and the semiconductor die 160 can include other components or features that are not shown. The semiconductor die 160 can also omit one or more of the components shown in FIG. 4 in some cases.

The semiconductor die 160 is similar to the semiconductor die 100 discussed with reference to FIG. 2 and includes a substrate 104. The semiconductor die 160 includes a first Group III nitride-based transistor 106 and a second Group III nitride-based transistor 112. The semiconductor die 160 includes output combiner inductor 118, RF output interface 120, first input matching circuit 122, second input matching circuit 126, DC blocking capacitor 130, first gate interface 134, second gate interface 136, first drain interface 138, second drain interface 140, first source interface 142, and second source interface 144 on the substrate 104.

As compared to the semiconductor die 100 of FIG. 2, the semiconductor die 160 of FIG. 4 includes an RF input power divider on the substrate 104 (e.g., an “on chip” RF input power divider). More particularly, the semiconductor die 160 includes a common RF input interface 164 that is coupled to both the first input matching circuit 122 and the second input matching circuit 126 (e.g., via the DC blocking capacitor 130 and an input combiner inductor 166).

In some examples, the RF input power divider on the semiconductor die 160 is not a Wilkinson input divider. Rather, the RF input power divider includes the common RF input interface 164, the first input matching circuit 122, the second input matching circuit 126, and the input combiner inductor 166. The input combiner inductor 166 may be a lumped element on the substrate 104 and may include a spiral inductor. The input combiner inductor 166 may be in a region of the semiconductor die 160 between the second input matching circuit 126 and the DC blocking capacitor 130. The impedance of the first input matching circuit 122, the second input matching circuit 126, the input combiner inductor 166, and other elements (e.g., the DC blocking capacitor 130) coupled to the common RF input interface 164 may provide the input RF power split between the first transistor 106 and the second transistor 112. The input combiner inductor 166 may facilitate having an RF input impedance for the semiconductor die 160 of about 10 Ohms or greater, although the RF input impedance can be greater or smaller than 10 Ohms in some cases.

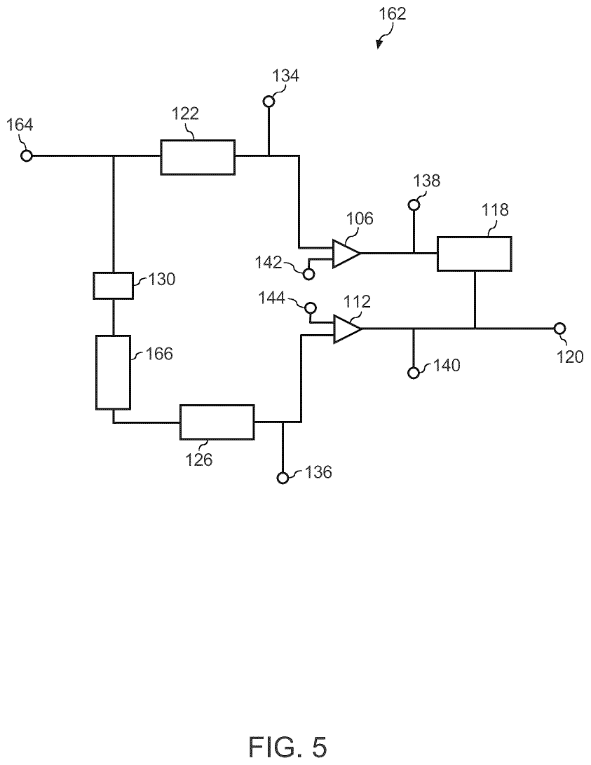

FIG. 5 is a circuit diagram corresponding to the amplifier circuit 162 on the semiconductor die 160 of FIG. 4. As shown, the amplifier circuit 162 includes an “on-chip” RF input power divider that includes the common RF input interface 164, the first input matching circuit 122, the second input matching circuit 126, and the input combiner inductor 166. The on-chip RF input power divider may divide an RF signal into a first RF signal and a second RF signal. The first RF signal may pass through the first input matching circuit 122 to the first transistor 106. The second RF signal may pass through the DC blocking capacitor 130, the input combiner inductor 166, and the second input matching circuit 126 to the second transistor 112. The output of the first transistor 106 may pass through the output combiner inductor 118 and combine with the output of the second transistor 112 to provide an RF output via the RF output interface 120 to a load.

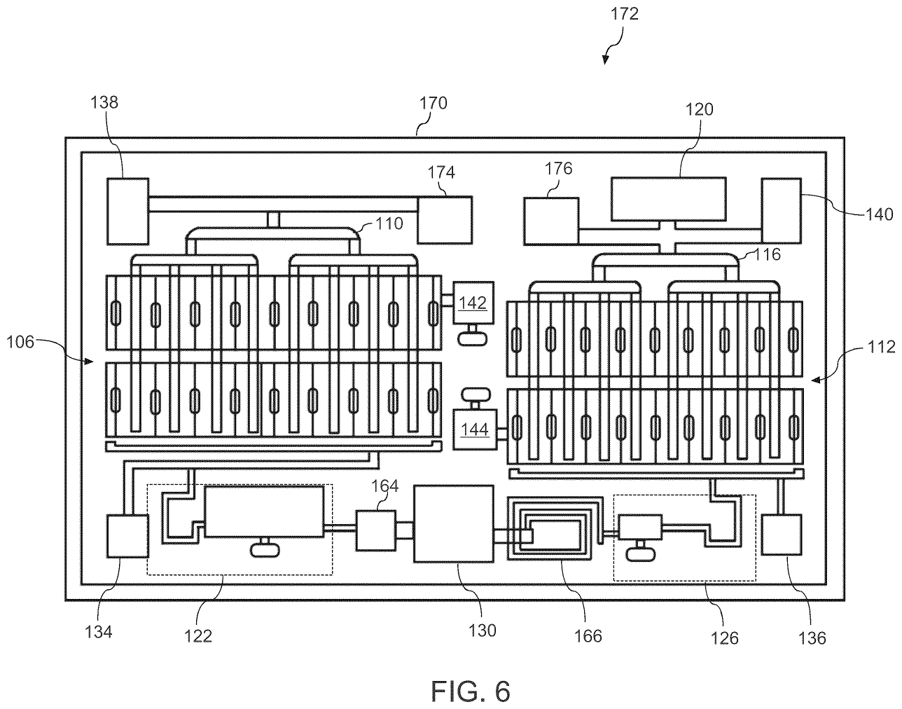

FIG. 6 depicts an example semiconductor die 170 that may be used to implement aspects of an amplifier circuit 172, such as a Doherty amplifier circuit, according to example embodiments of the present disclosure. The semiconductor die 170 may be associated with a MMIC including a range of active and passive circuit components implemented over a single common substrate in one example, but the semiconductor die 170 is not limited to implementation as a MMIC in all cases. The semiconductor die 170 is provided as a representative example. The features of the semiconductor die 170 are not exhaustively illustrated, and the semiconductor die 170 can include other components or features that are not shown. The semiconductor die 170 can also omit one or more of the components shown in FIG. 6 in some cases. The semiconductor die 170 is similar to the semiconductor die 160 discussed with reference to FIG. 4 and includes a substrate 104. The semiconductor die 170 includes a first Group III nitride-based transistor 106 and a second Group III nitride-based transistor 112. The semiconductor die 170 includes a common RF input interface 164, RF output interface 120, first input matching circuit 122, second input matching circuit 126, DC blocking capacitor 130, input combiner inductor 166, first gate interface 134, second gate interface 136, first drain interface 138, second drain interface 140, first source interface 142, and second source interface 144 on the substrate 104.

As compared to the semiconductor die 100 of FIG. 4, the semiconductor die 170 of FIG. 6 includes an interface for an “off chip” output combiner inductor. For instance, the semiconductor die 170 includes a first output combiner interface 174 and a second output combiner interface 176 on the substrate 104. The first output combiner interface 174 and the second output combiner interface 176 may provide an interface for connecting a larger output combiner inductor located off chip. The larger output combiner inductor may be suitable for use at lower operational frequencies, such as operational frequencies in a range of about 1.8 GHz or less, such as in a range of about 400 MHz to about 1.8 GHZ, although other operational frequencies can be relied upon.

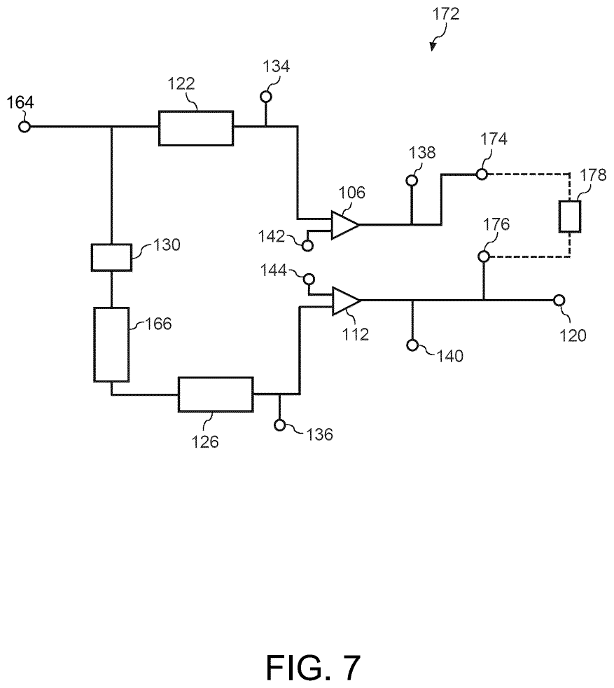

FIG. 7 depicts a circuit diagram corresponding to the amplifier circuit 172 on the semiconductor die 170 of FIG. 6. As shown, the amplifier circuit 172 includes an “on-chip” RF input power divider that includes the common RF input interface 164, the first input matching circuit 122, the second input matching circuit 126, and the input combiner inductor 166. The on-chip RF input power divider may divide an RF signal into a first RF signal and a second RF signal. The first RF signal may pass through the first input matching circuit 122 to the first transistor 106. The second RF signal may pass through the DC blocking capacitor 130, the input combiner inductor 166, and the second input matching circuit 126 to the second transistor 112. The output of the first Group III nitride-based transistor 106 may pass through an off-chip output combiner inductor 178 (e.g., via first output combiner interface 174 and second output combiner interface 176) and combine with the output of the second transistor 112 to provide an RF output via the RF output interface 120 to a load.

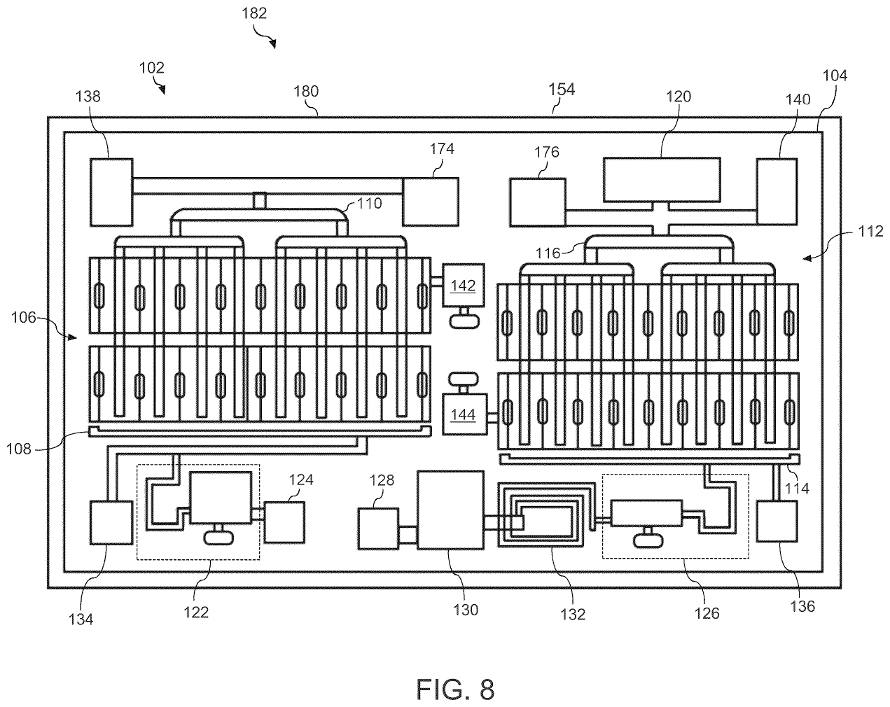

FIG. 8 depicts an example semiconductor die 180 that may be used to implement aspects of an amplifier circuit 182, such as a Doherty amplifier circuit, according to example embodiments of the present disclosure. The semiconductor die 180 may be associated with a MMIC including a range of active and passive circuit components implemented over a single common substrate in one example, but the semiconductor die 180 is not limited to implementation as a MMIC in all cases. The semiconductor die 180 is provided as a representative example. The features of the semiconductor die 180 are not exhaustively illustrated, and the semiconductor die 180 can include other components or features that are not shown. The semiconductor die 180 can also omit one or more of the components shown in FIG. 6 in some cases.

The semiconductor die 180 is similar to the semiconductor die 100 discussed with reference to FIG. 2 and includes a substrate 104. The semiconductor die 170 includes a first Group III nitride-based transistor 106 and a second Group III nitride-based transistor 112. The semiconductor die 180 includes a first RF input interface 124 and a second RF input interface 128 on the substrate 104 for coupling to an off-chip RF input power divider. The semiconductor die 180 includes an RF output interface 120, first input matching circuit 122, second input matching circuit 126, DC blocking capacitor 130, phase shifter inductor 132, first gate interface 134, second gate interface 136, first drain interface 138, second drain interface 140, first source interface 142, and second source interface 144 on the substrate 104. The semiconductor die 180 includes an interface for an “off chip” output combiner inductor. For instance, the semiconductor die 180 includes a first output combiner interface 174 and a second output combiner interface 176 on the substrate 104.

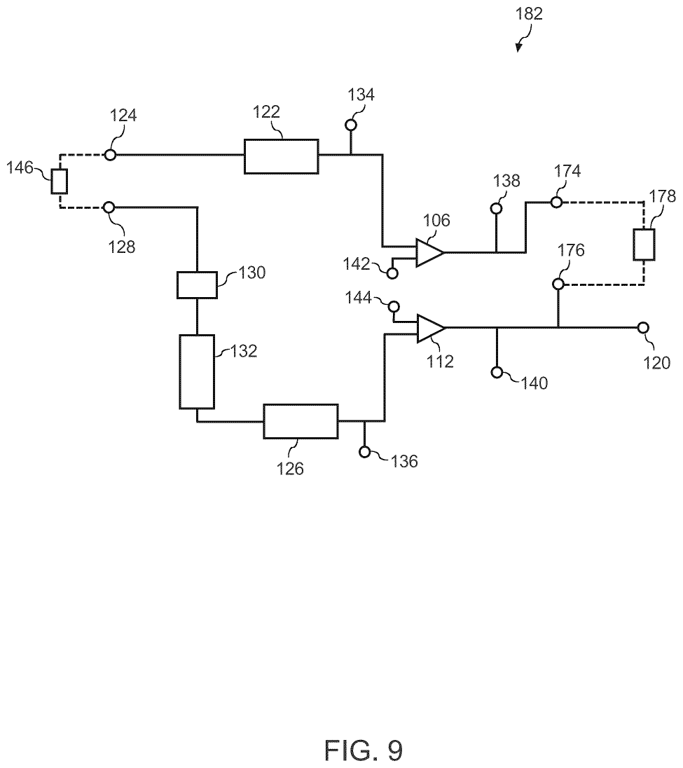

FIG. 9 depicts a circuit diagram corresponding to the amplifier circuit 182 on the semiconductor die 180 of FIG. 8. An “off chip” RF input power divider 146 (e.g., Wilkinson input divider) may divide an input RF signal and provide a RF signal to the first RF input interface 124 on the semiconductor die 180 and a second RF signal to the second RF input interface 128 on the semiconductor die 180. The first RF signal may pass through the first input matching circuit 122 to the first transistor 106. The second RF signal may pass through the DC blocking capacitor 130, the phase shifter inductor 132, and the second input matching circuit 126 to the second transistor 112. The output of the first transistor 106 may pass through an off-chip output combiner inductor 178 (e.g., via first output combiner interface 174 and second output combiner interface 176) and combine with the output of the second transistor 112 to provide an RF output via the RF output interface 120 to a load.

In other aspects of the embodiments, FIG. 10 depicts a cross-sectional view of an example unit cell Group III nitride-based transistor device 200, which is an example of a HEMT device (also “HEMT 200”). The HEMT 200 can be used to implement at least a portion of, for instance, the first Group III nitride-based transistor 106 and/or the second Group III nitride-based transistor 112. The transistors 106 and 112 can be implemented and embodied as other types of transistors, however. The example HEMT 200 is provided for purposes of illustration and discussion. Those of ordinary skill in the art, using the disclosures provided herein, will understand that other Group III nitride-based transistor devices may be used as the first Group III nitride-based transistor 106 and/or the second Group III nitride-based transistor 112. FIG. 10 is an example and intended to represent structures for identification and description and is not intended to represent the structures to physical scale.

The HEMT 200 may include a semiconductor structure 202. The semiconductor structure 202 may be a Group III nitride semiconductor structure. The semiconductor structure 202 may be metal-polar. However, aspects of the present disclosure are applicable to semiconductor devices having N-polar semiconductor structures without deviating from the scope of the present disclosure.

As shown, the semiconductor structure 202 is implemented at least in part in, on, and over be on a substrate 104. As described above, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate 104 may be a High Purity Semi-Insulating (HPSI) substrate in some cases. The term “semi-insulating” is used descriptively herein, rather than in an absolute sense.

In some embodiments, the SiC bulk crystal of the substrate 104 may have a resistivity equal to or higher than about 1×10⁵ Ohm-cm at room temperature. Example SiC substrates that may be used in some embodiments and methods for producing such substrates are described, for example, in U.S. Pat. No. Re. 34,861 and U.S. Pat. Nos. 4,946,547, 5,200,022, and 6,218,680, the disclosures of which are hereby incorporated herein by reference. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like.

The substrate 104 may have a lower surface 104A and an upper surface 104B. In some embodiments, the substrate 104 of the HEMT 200 may be a thinned substrate 104. In some embodiments, the thickness of the substrate 104 (i.e., as measured in a vertical direction from the top to the bottom of the page in FIG. 10) may be about 100 μm or less, such as about 75 μm or less, such as about 50 μm or less.

The HEMT 200 may include a channel layer 206 on the upper surface 104B of the substrate 104 (or on the optional layers described further herein, such as an optional buffer layer or nucleation layer). The HEMT 200 may include a barrier layer 208 on an upper surface of the channel layer 206. In some embodiments, the channel layer 206 and the barrier layer 208 may each be formed by epitaxial growth. Techniques for epitaxial growth of Group III nitrides have been described in, for example, U.S. Pat. Nos. 5,210,051, 5,393,993, and 5,523,589, the entire disclosures of which are hereby incorporated herein by reference. The channel layer 206 may have a bandgap that is less than the bandgap of the barrier layer 208. The channel layer 206 may have a larger electron affinity than the barrier layer 208. The channel layer 206 and the barrier layer 208 may include Group III-nitride based or gallium nitride materials.

In some embodiments, the channel layer 206 may be a Group III nitride layer, such as AlₓGa(₁₋ₓ)N, where the aluminum mole fraction x is 0≤x<1, provided that the energy of the conduction band edge of the channel layer 206 is less than the energy of the conduction band edge of the barrier layer 208 at the interface between the channel layer 206 and barrier layer 208. In some embodiments, the aluminum mole fraction x is approximately 0, indicating that the channel layer 206 is GaN. The channel layer 206 may or may not include other Group III-nitrides such as InGaN, AlInGaN or the like. The channel layer 206 may be undoped (“unintentionally doped”) and may be grown to a thickness in the range of about 0.5 μm to about 5 μm, such as about 2 μm, and other thicknesses can be relied upon. The channel layer 206 may be a multi-layer structure, such as a superlattice or combinations of GaN, AlGaN or the like. The channel layer 206 may be under compressive strain in some embodiments.

The semiconductor structure 202 may include a barrier layer 208 on an upper surface of the channel layer 206. The barrier layer 208 may have a bandgap that is different from the bandgap of the channel layer 206. The energy of the conduction band edge of the barrier layer 208 may be greater than the energy of the conduction band edge of the channel layer 206 at the interface between the channel layer 206 and the barrier layer 208. The barrier layer 208 may be a Group III-nitride layer, such as AlₓGa(₁₋ₓ)N, where x is the aluminum mole fraction in the barrier layer 208. In some embodiments, the aluminum mole fraction x is such that x is in a range of about 0.15 to about 0.40, such as about 0.20 to about 0.25, such as about 0.22 (e.g., the aluminum mole fraction is in a range of 15% to 40%, such as in a range of about 20% to about 25%, such as about 22%), indicating that the barrier layer is an AlGaN layer.

The barrier layer 208 may include other Group III elements (e.g., In) without deviating from the scope of the present disclosure. The barrier layer 208, in some examples, may be a multilayer structure. The multilayer structure may include multiple Group III nitride-based layers with differing aluminum mole fractions. The barrier layer 208 may have a thickness in a range of about 10 Angstroms to about 300 Angstroms, such as about 120 Angstroms to about 170 Angstroms, such as about 150 Angstroms, and other thicknesses can be relied upon. The channel layer 206 and/or the barrier layer 208 may be deposited, for example, by metal-organic chemical vapor deposition (MOCVD), molecular beam epitaxy (MBE), or hydride vapor phase epitaxy (HVPE). A two-dimensional electron gas (2DEG) 210 may be induced in the channel layer 206 at an interface between the channel layer 206 and the barrier layer 208. The 2DEG 210 is highly conductive and allows conduction between the source and drain regions of the HEMT 200.

While the HEMT 200 is shown with a substrate 104, channel layer 206, and barrier layer 208 for purposes of illustration, the HEMT 200 may include additional layers/structures/elements. For instance, the HEMT 200 may include a buffer layer and/or nucleation layer(s) between substrate 104 and the channel layer 206. For example, an AlN buffer layer may be on the upper surface 104B of the substrate 104 to provide an appropriate crystal structure transition between a SiC substrate and the channel layer 206. The optional buffer/nucleation/transition layers may be deposited by MOCVD, MBE, and/or HYPE.

The HEMT 200 may include a cap layer on the barrier layer 208. HEMT structures including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the entire disclosures of which are hereby incorporated herein by reference. Additionally, strain balancing transition layer(s) may also and/or alternatively be provided as described, for example, in U.S. Pat. No. 7,030,428, the disclosure of which is incorporated by reference herein.

The HEMT 200 may include a source contact 212 on an upper surface 208A of the barrier layer 208 or otherwise contacting the barrier layer 208. The HEMT 200 may include a drain contact 214 on the upper surface 208A of the barrier layer 208 or otherwise contacting the barrier layer 208. The source contact 212 and the drain contact 214 may be laterally spaced apart from each other. In some embodiments, the source contact 212 and the drain contact 214 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSix, titanium silicide (TiSi), titanium nitride (TiN), tungsten silicon nitride (WSiN), platinum (Pt) and the like. In some embodiments, the source contact 212 may be an ohmic source contact 212. The drain contact 214 may be an ohmic drain contact 214. Thus, the source contact 212 and/or the drain contact 214 may include an ohmic contact portion in direct contact with the barrier layer 208. In some embodiments, the source contact 212 and/or the drain contact 214 may include a plurality of layers to form an ohmic contact that may be provided as described, for example, in U.S. Pat. Nos. 8,563,372 and 9,214,352, the entire disclosures of which are hereby incorporated herein by reference.

The HEMT 200 may include a gate contact 216 on the upper surface 208A of the barrier layer 208 or otherwise contacting the barrier layer 208 (e.g., recessed into the barrier layer 208). The gate contact 216 may have a gate length LG. The gate length LG may be the length of the gate contact 216 at the portion of the gate contact 216 that is on the semiconductor structure 202 as illustrated in FIG. 10. In some embodiments, the gate length LG may be in the range of about 100 nm to about 400 nm, such as about 100 nm to about 350 nm. In some embodiments, the gate length LG may be about 100 nm or less, such as about 90 nm or less, such as about 60 nm or less. In some embodiments, the gate length LG may be in a range of about 40 nm to about 90 nm.

The material of the gate contact 216 may be chosen based on the composition of the barrier layer 208, and may, in some embodiments, be a Schottky contact. Materials capable of making a Schottky contact to a Group III-nitride based semiconductor material may be used, such as, for example, nickel (Ni), platinum (Pt), nickel silicide (NiSix), copper (Cu), palladium (Pd), chromium (Cr), tungsten (W) and/or tungsten silicon nitride (WSiN).

The source contact 212 may be coupled to a reference signal such as, for example, a ground voltage or other reference signal. The coupling to the reference signal may be provided by a via 218 that extends from a lower surface 104A of the substrate 104, through the substrate 104 and the channel layer 206 to the upper surface 208A of the barrier layer 208. The via 218 may expose a bottom surface of the ohmic portion 212A of the source contact 212. A back metal layer 220 may be on the lower surface 104A of the substrate 104 and on side walls of the via 218. The back metal layer 220 may directly contact the ohmic portion 212A of the source contact 212. In some embodiments a contact area between the back metal layer 220 and the bottom surface of the ohmic portion 212A of the source contact 212 may be fifty percent or more of an area of the bottom surface of the ohmic portion 212A of the source contact 212. Thus, the back metal layer 220, and a signal coupled thereto, may be electrically connected to the source contact 212.

In some embodiments, the via 218 may have an oval or circular cross-section when viewed in a plan view. However, the present disclosure is not limited thereto. In some embodiments, a cross-section of the via 218 may be a polygon or other shape, as will be understood by one of ordinary skill in the art using the disclosures provided herein. In some embodiments, dimensions of the via (e.g., a length and/or a width) may be such that a largest cross-sectional area A1 of the via 218 is about 1000 μm² or less. The cross-sectional area A1 may be taken in a direction that is parallel to the lower surface 104A of the substrate 104 (e.g., the X-Y plane of FIG. 10). In some embodiments, the largest cross-sectional area A1 of the via 218 may be that portion of the via 218 that is adjacent to the lower surface 104A of the substrate 104 (e.g., the opening of the via 218). For example, in some embodiments, a greatest width (e.g., in the X direction from right to left on the page in FIG. 10) may be about 16 μm and a greatest length (e.g., in the Y direction from top to bottom on the page in FIG. 10) may be about 40 μm, though the present disclosure is not limited thereto. In some embodiments, sidewalls of the via 218 may be inclined and/or slanted with respect to the lower surface 104A of the substrate 104. In some embodiments, the sidewalls of the via 218 may be approximately perpendicular to the lower surface 104A of the substrate 104.

The drain contact 214 may be formed on, in, and/or through the barrier layer 208, and there can be ion implantation into the materials around the drain contact 214 (e.g., through the barrier layer 208 and into the channel layer 206) to reduce resistivity and provide improved ohmic contact to the semiconductor material. In yet other embodiments, there is no source via 218, and the source contact 212 is formed on, in, and/or through the barrier layer 208, and there can be ion implantation in the materials around the source contact 212 to reduce resistivity and provide improved ohmic contact to the semiconductor material.

The HEMT 200 may include a first insulating layer 222. The first insulating layer 222 may directly contact the upper surface of the semiconductor structure 202 (e.g., contact the upper surface 208A of the barrier layer 208). The HEMT 200 may include a second insulating layer 224. The second insulating layer 224 may be on the first insulating layer 222. It will also be appreciated that more than two insulating layers may be included in some embodiments. The first insulating layer 222 and/or the second insulating layer 224 may serve as passivation layers for the HEMT 200. The first insulating layer 222 and/or the second insulating layer 224 may be dielectric layers. Different dielectric materials may be used such as a SiN, SiO₂, Al₂O₃, MgOx, MgNx, ZnO, SiNx, SiOx, alloys or layer sequences thereof, or epitaxial materials.

The source contact 212, the drain contact 214, and the gate contact 216 may be in the first insulating layer 222. In some embodiments, at least a portion of the gate contact 216 may be on the first insulating layer 222. In some embodiments, the gate contact 216 may be a T-shaped gate and/or a gamma gate, the formation of which is discussed by way of example in U.S. Pat. Nos. 8,049,252, 7,045,404, and 8,120,064, the entire disclosures of which are hereby incorporated herein by reference. The second insulating layer 224 may be on the first insulating layer 222 and on portions of the source contact 212, drain contact 214, and gate contact 216. The protrusions from the gate can also be referred to as a field plate integrated with the gate.

A field plate 226 may optionally be on the second insulating layer 224 as illustrated in FIG. 10, or on another insulating layer depending on the number of insulating layers included in the HEMT 200. At least a portion of a field plate 226 may be at least partially overlapping the gate contact 216. At least a portion of the field plate 226 may be on a portion of the second insulating layer 224 that is between the gate contact 216 and the drain contact 214. The field plate 226 may reduce the peak electric field in the HEMT 200, which may result in increased breakdown voltage and reduced charge trapping. The reduction of the electric field can also yield other benefits such as reduced leakage currents and enhanced reliability. Field plates and techniques for forming field plates are discussed, by way of example, in U.S. Pat. No. 8,120,064, the disclosure of which is incorporated by reference herein.

Metal contacts 228 may be disposed in the second insulating layer 224 as illustrated in FIG. 10, or on another insulating layer depending on the number of insulating layers included in the HEMT 200. The metal contacts 228 may provide interconnection between the source contact 212 and other parts of an integrated circuit including the HEMT 200. Respective ones of the metal contacts 228 may directly contact respective ones of the drain contact 214 and/or source contact 212. The metal contacts 228 may include metal or other highly conductive material, including, for example, copper, cobalt, gold, and/or a composite metal.

The HEMT 200 may be formed by the active region between the source contact 212 and the drain contact 214 under the control of a gate contact 216 between the source contact 212 and the drain contact 214. FIG. 10 depicts a cross-sectional view of one unit of an HEMT 200 for purposes of illustration. The HEMT 200 may be formed adjacent to additional HEMT device units and may share, for instance, a source contact 212 with adjacent HEMT device units.

The transistors and other active devices described herein can be formed using Group III nitride-based, Group III-V, and related semiconductor materials and semiconductor manufacturing processes. The Group III elemental materials include scandium (Sc), aluminum (Al), gallium (Ga), and indium (In), and the Group V elemental materials include nitrogen (N), phosphorus (P), arsenic (As), and antimony (Sb)). Thus, in some examples, the concepts can be applied to Group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The embodiments and concepts described herein can be applied to semiconductor die amplifier circuits implemented in, on, and over silicon (e.g., GaN-on-Si), silicon carbide (e.g., GaN-on-silicon carbide (SiC)), gallium arsenide (GaAs), as well as other types of substrate materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (Alₓ In_{y}Ga_{(1-x-y)}N), gallium arsenide phosphide nitride (GaAsₐ P_{b} N_{(1-a-b)}), aluminum indium gallium arsenide phosphide nitride (AlₓIn_{y}Ga_{(1-x-y)} ASₐP_{b}N_{(1-a-b)}), among others. The gallium nitride materials can be n-type doped, p-type doped, or unintentionally doped (UID). The gallium nitride materials can be formed over a silicon, silicon carbide, or other type of substrate. The term “gallium nitride” or GaN semiconductor refers directly to gallium nitride, exclusive of its alloys.

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0).

The transistors described herein can be formed as field effect transistors (FETs), although the concepts can be applied to other types of transistors. Among other types of FET transistors, the transistors described herein can be formed as HEMTs, pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates.

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially-available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

As described herein, a reference to the “thickness” of a substrate or material layer is a measurement of the cross-sectional thickness of the substrate or layer measured from the top surface of the substrate or layer to the bottom surface of the substrate or layer, such as from the top to the bottom of the page. Additionally, a “top” or “top surface” of a layer is positioned toward the top of the page, and a “bottom” or “bottom surface” of a layer is positioned toward the bottom of the page, unless otherwise specified.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. A semiconductor die comprising:
a first Group III nitride-based transistor over a substrate and having a first output contact;
a second Group III nitride-based transistor over the substrate and having a second output contact;
an output combiner inductor over the substrate, the output combiner inductor being coupled to the first output contact and to the second output contact; and
a radio frequency (RF) output interface coupled to the output combiner inductor.

2. The semiconductor die of claim 1, further comprising:
a first RF input interface coupled to the first Group III nitride-based transistor; and
a second RF input interface coupled to the second Group III nitride-based transistor.

3. The semiconductor die of claim 1, further comprising:
a first gate interface coupled to a gate of the first Group III nitride-based transistor; and
a second gate interface coupled to a gate of the second Group III nitride-based transistor.

4. The semiconductor die of claim 1, further comprising:
a first drain interface for the first Group III nitride-based transistor; and
a second drain interface for the second Group III nitride-based transistor.

5. The semiconductor die of claim 1, wherein the output combiner inductor is configured to implement a phase shift in an RF signal output by the first Group III nitride-based transistor.

6. The semiconductor die of claim 1, wherein the output combiner inductor comprises a spiral inductor.

7. The semiconductor die of claim 1, wherein the output combiner inductor is positioned in a region of the semiconductor die between a first drain interface and a second drain interface.

8. The semiconductor die of claim 7, wherein the RF output interface is positioned in a region of the semiconductor die between the output combiner inductor and the second drain interface.

9. The semiconductor die of claim 1, wherein the output combiner inductor is positioned in a region of the semiconductor die outside of a region defined between the first Group III nitride-based transistor and the second Group III nitride-based transistor.

10. The semiconductor die of claim 1, further comprising:
a first input matching circuit over the substrate and coupled to a first gate interface of the first Group III nitride-based transistor; and
a second input matching circuit over the substrate and coupled to a second gate interface of the second Group III nitride-based transistor.

11. The semiconductor die of claim 10, further comprising:
a first RF input interface coupled to the first input matching circuit; and
a second RF input interface coupled to the second input matching circuit.

12. The semiconductor die of claim 11, further comprising a phase shifter inductor over the substrate and positioned in a region of the semiconductor die between the second RF input interface and the second input matching circuit.

13. The semiconductor die of claim 12, wherein the first input matching circuit and the second input matching circuit are coupled to a common RF input interface of the semiconductor die.

14. The semiconductor die of claim 13, further comprising an input combiner inductor over the substrate and positioned in a region of the semiconductor die between the common RF input interface and the second input matching circuit.

15. The semiconductor die of claim 10, further comprising a blocking capacitor over the substrate and coupled to the second input matching circuit.

16. The semiconductor die of claim 10, wherein:
the output combiner inductor is positioned in a first region of the semiconductor die, the first Group III nitride-based transistor and the second Group III nitride-based transistor are positioned in a second region of the semiconductor die, and the first input matching circuit and the second input matching circuit are positioned in a third region of the semiconductor die; and
the second region of the semiconductor die is positioned between the first region of the semiconductor die and the third region of the semiconductor die.

17. The semiconductor die of claim 1, wherein the first Group III nitride-based transistor comprises a first plurality of transistor unit cells and the second Group III nitride-based transistor comprises a second plurality of transistor cells.

18-50. (canceled)
